(19) United States
(12) Patent Application Publication
(10) Pub. No.: US 2021/0399667 A1
(43) Pub. Date: Dec. 23, 2021

(54) Power Module for Operating an Electric Vehicle Drive with an Intermediate Circuit Capacitor

(71) Applicant: ZF Friedrichshafen AG, Friedrichshafen (DE)

(72) Inventor: Wei Liu, Friedrichshafen (DE)

(21) Appl. No.: 17/353,113

(22) Filed: Jun. 21, 2021

(30) Foreign Application Priority Data
Jun. 22, 2020 (DE) 10 2020 207 701.0

(51) Int. Cl. H02P 27/06; B60L 50/51

(52) U.S. Cl. CPC H02P 27/06; B60L 2210/40; B60L 50/51

(57) ABSTRACT

A power module (10) for operating an electric vehicle drive includes a plurality of circuit-breakers (114, 116, 124, 126, 134, 136) for generating an output current based on a supplied input current. The multiple circuit-breakers (114, 116, 124, 126, 134, 136) have multiple groups (115, 125, 135), each of which includes two circuit-breakers (114, 116, 124, 126, 134, 136) connected to each other in series. An intermediate circuit arrangement is connected in parallel to the circuit-breakers (114, 116, 124, 126, 134, 136). The intermediate circuit capacitor arrangement includes a plurality of intermediate circuit capacitors (112, 122, 132), each of which is assigned to a respective one of the multiple groups (115, 125, 135) of the circuit-breakers (114, 116, 124, 126, 134, 136), in order to form a sub-module (102, 104, 106) with the particular groups (115, 125, 135).

### CROSS-REFERENCE TO RELATED APPLICATION

The present application is related and has right of priority to German Patent Application No. 102020207701.0 filed in the German Patent Office on Jun. 22, 2020, which is incorporated by reference in its entirety for all purposes.

### TECHNICAL FIELD

The present invention relates generally to the field of electromobility, in particular of the power modules for operating an electric drive for a vehicle.

### TECHNICAL BACKGROUND

Power modules, in particular integrated power modules, are increasingly being used in motor vehicles. These types of power modules are used, for example, in DC/AC inverters, which are utilized for energizing electric machines, such as electric motors, with a multiphase alternating current. In the process, a direct current generated by a DC energy source, for example, a battery, is converted into a multiphase alternating current. The power modules are based on power semiconductors, in particular transistors, such as IGBTs, MOSFETs, and HEMTs. Further fields of use are DC/DC converters and AC/DC rectifiers (converters) and transformers.

The power semiconductors are generally used for forming circuit-breakers, which are utilized in a bridge circuit. A frequent example is the half-bridge, which includes a high-side component and a low-side component. The high-side and low-side components each include one or multiple circuit-breaker(s), namely high-side circuit- breakers and low-side circuit-breakers. By switching the high-side and low-side circuit- breakers in a targeted manner, the direction of the current (output current) generated at the output of the power module can be changed, with a very short cycle, between a positive current direction and a negative current direction. This allows for pulse width modulation, in order to generate, in the case of a DC/AC inverter, an alternating current based on a direct current supplied on the input side of the power module.

In all these applications, it is advantageous that the switching time of the utilized circuit-breakers is sufficiently short. Due to the advances made in the field of power semiconductors, short switching times can be implemented with wide-bandgap semiconductors, such as silicon carbide (SiC) and gallium nitride (GaN).

Nevertheless, short switching times have the disadvantage that the short switching times induce high voltages during the switching on and off of the circuit- breakers when leakage inductance prevails in the power lines of the power module. High voltages can cause the circuit-breakers and/or the power semiconductors contained therein to blow and, thereby, become adversely affected. Intermediate capacitors, which reduce and/or flatten the arising voltage peaks, are already used in power modules known from the prior art. This voltage-smoothing effect is not sufficient, however, due to the design, for protecting the power semiconductors from blowing in the case of the known power modules.

### BRIEF SUMMARY OF THE INVENTION

Example aspects of the invention better protecting the power semiconductors against blowing due to voltage peaks during the switching on and off, in order to increase the performance of the power module.

A power module within the scope of example aspects of the invention is utilized for operating an electric drive of a vehicle, in particular of an electric vehicle and/or a hybrid vehicle. The power module is preferably utilized in a DC/AC inverter. In particular, the power module is utilized for energizing an electric machine, for example, an electric motor and/or a generator. A DC/AC inverter is utilized for generating a multiphase alternating current from a direct current generated by a DC voltage of an energy source, for example, a battery.

In order to supply an input current (direct current), the power module preferably has an input contact having a positive pole and a negative pole. During operation of the power module, the positive pole is electrically conductively connected to a positive terminal of the battery, wherein the negative pole is electrically conductively connected to a negative terminal of the battery.

The power module also includes a plurality of circuit-breakers, which are connected in parallel to the snubber capacitor. These semiconductor-based circuit- breakers are utilized for generating an output current, based on the supplied input current, by actuating the individual circuit-breakers. The actuation of the circuit-breakers can be based on pulse width modulation.

The multiple circuit-breakers are divided into multiple groups. Each of the multiple groups (or circuit-breaker groups) has two circuit-breakers connected to each other in series. Preferably, a bridge circuit arrangement is formed from the circuit-breakers. The bridge circuit arrangement can include one or multiple bridge circuit(s), which are designed, for example, as half-bridges. Each half-bridge includes one high-side switch (HS switch) or multiple high-side switches connected to one another in parallel and one low-side switch (LS switch) or multiple low-side switches connected to one another in parallel. The HS switch(es) is/are connected in series to the LS switch(es). In this case, each half-bridge forms a circuit-breaker group. Each half-bridge is associated with a current phase of a multiphase alternating current (output current). The HS switches and LS switches each include one or multiple power semiconductor components such as IGBT, MOSFET, or HEMT. The semiconductor material forming the basis of the particular power semiconductor component preferably includes a wide-bandgap semiconductor, such as silicon carbide (SiC) or gallium nitride (GaN). Alternatively or additionally, the wide-bandgap semiconductor can contain silicon.

For the purpose of voltage-smoothing, the power module further includes an intermediate circuit capacitor arrangement, which is connected in parallel to the circuit- breakers. The intermediate circuit capacitor arrangement includes multiple intermediate circuit capacitors, which are designed, for example, as parallel plate capacitors. Each of the intermediate circuit capacitors is assigned to one of the multiple circuit-breaker groups. Therefore, all intermediate circuit capacitors are each assigned to all circuit- breaker groups in a one-to-one allocation.

The power module also preferably includes an insulating substrate for the mounting of the circuit-breakers. The insulating substrate includes, for example, a first metal layer, a second metal layer, and an insulating layer arranged between the first metal layer and the second metal layer. This is preferably a direct bonded copper (DCB) insulating substrate. The circuit-breakers are mounted on the first metal layer. For example, the circuit-breakers are secured on the first metal layer by sintering, welding, soldering, or by a screw/fastener connection.

The power module preferably further includes a heat sink, which is designed for dissipating heat that is produced in the power module, in particular in the circuit- breakers, at high input currents.

Due to the fact that the power module includes not only one single intermediate circuit capacitor, but rather multiple intermediate circuit capacitors, which are fixedly assigned to the various circuit-breaker groups in a one-to-one allocation, the flexibility with regard to the arrangement of the intermediate circuit capacitors in the power module is increased. This justifies a shorter electrical line between each intermediate circuit capacitor and the associated circuit-breaker group. The leakage inductance, which is related to the length of the electrical line, is therefore reduced. The probability that voltage peaks occur during the switching on and off of the circuit-breakers is therefore reduced. The circuit-breakers are therefore at a reduced risk of blowing or are completely protected against a risk of this type, which would otherwise be feared in the case of the leakage inductance in the power module when WBG semiconductor materials are used, due to the very short switching times of these materials. The functionability of the power module is therefore increased.

### BRIEF DESCRIPTION OF THE DRAWING

Embodiments are now described by way of example and with reference to the attached drawings, wherein:

FIG. 1 shows a schematic of a circuit for a power module according to one example embodiment;

FIG. 2 shows a schematic of a sub-module of a power module according to a further example embodiment, in a side view;

FIG. 3 shows a schematic of the power module made up of multiple sub-modules shown in FIG. 2, in a side view; and

FIG. 4 shows a schematic of the sub-module from FIG. 2 in a further side view.

In the figures, identical reference characters refer to identical or functionally identical purchased parts. The particular relevant purchased parts are labeled in the individual figures.

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

FIG. 1 shows a schematic of a circuit for a power module 10 according to one example embodiment. The power module 10 is utilized primarily for the application in a DC/AC inverter, which converts a supplied direct current into a multiphase alternating current. The alternating current has, for example, three current phases, which are shifted with respect to one another by a phase angle of one hundred and twenty (120) degrees. The power module 10 is represented here in a simplified manner and includes three submodules 102, 104, 106. Each of the three submodules 102, 104, 106 is assigned to one of the three current phases. The fact that this is a three-phase alternating current is only one exemplary application of the present invention.

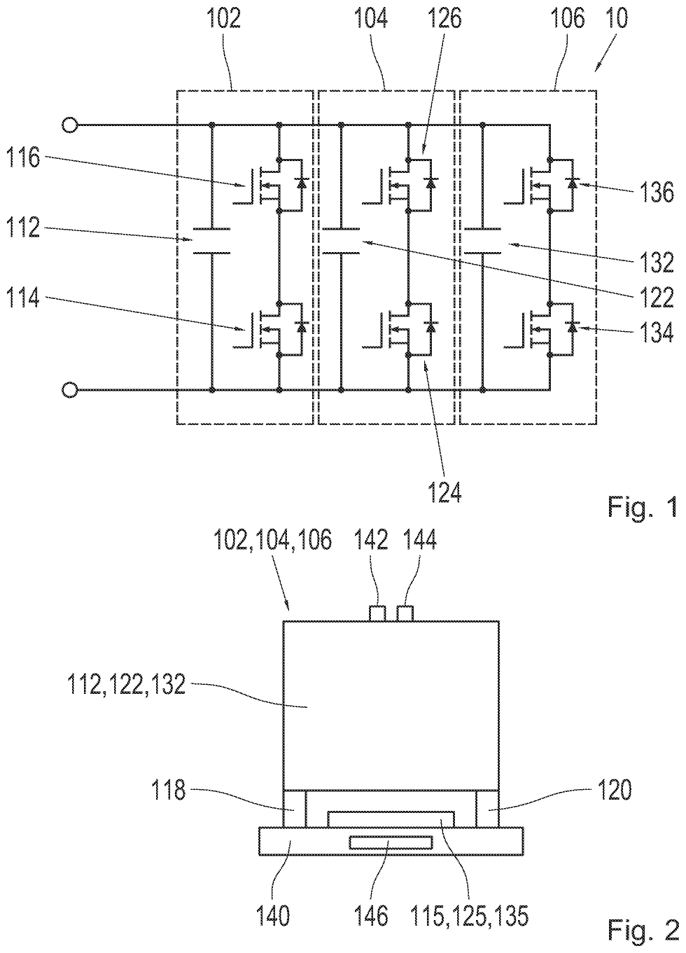

Each submodule 102, 104, 106 has a half-bridge, which includes a group 115, 125, 135 (see FIG. 2) made up of one or multiple high-side switch(es) 116, 126, 136 and one or multiple low-side switch(es) 114, 124, 134. In the case that the half-bridge includes multiple high-side switches and/or low-side switches, the multiple high-side switches are connected to one another in parallel, wherein the multiple low-side switches are connected to one another in parallel. Within a half-bridge, the high-side switch(es) is/are connected in series to the low-side switch(es).

Each sub-module 102, 104, 106 further includes an intermediate circuit capacitor 112, 122, 132, which is connected in parallel to the circuit-breakers in the particular sub- module 102, 104, 106. In the example shown in FIG. 1, therefore, three intermediate circuit capacitors 112, 122, 132 are contained, which are assigned to the three half- bridges or circuit-breaker groups 115, 125, 135 in a one-to-one or respective allocation. Each intermediate circuit capacitor 112, 122, 132 forms, with the associated half-bridge or circuit-breaker group 115, 125, 135, the corresponding sub-module 102, 104, 106.

FIG. 2 shows the particular sub-module 102, 104, 106 in a side view. According to a further example embodiment, the intermediate circuit capacitor 112, 122, 132 is arranged situated on a substrate 140. The intermediate circuit capacitor 112, 122, 132 is secured at the substrate 140, on the substrate side, by two connecting elements 118, 120 (for example, a screw connection or an adhesive bond). The corresponding half- bridge 115, 125, 135 or circuit-breaker group is arranged between the intermediate circuit capacitor 112, 122, 132 and the substrate 140. The substrate 140 can include a direct bonding copper (DCB) substrate. The substrate 140 can be connected, at the side facing away from the intermediate circuit capacitor 112, 122, 132, to a heat sink (not shown).

A current input including a positive pole 142 and a negative pole 144 is arranged here, by way of example, on a top side of the intermediate circuit capacitor 112, 122, 132. This is arrangement is provided by way of example only and is not limiting for the present invention, however. Another positioning of the current input is conceivable. A current output 146 is secured at the substrate 140.

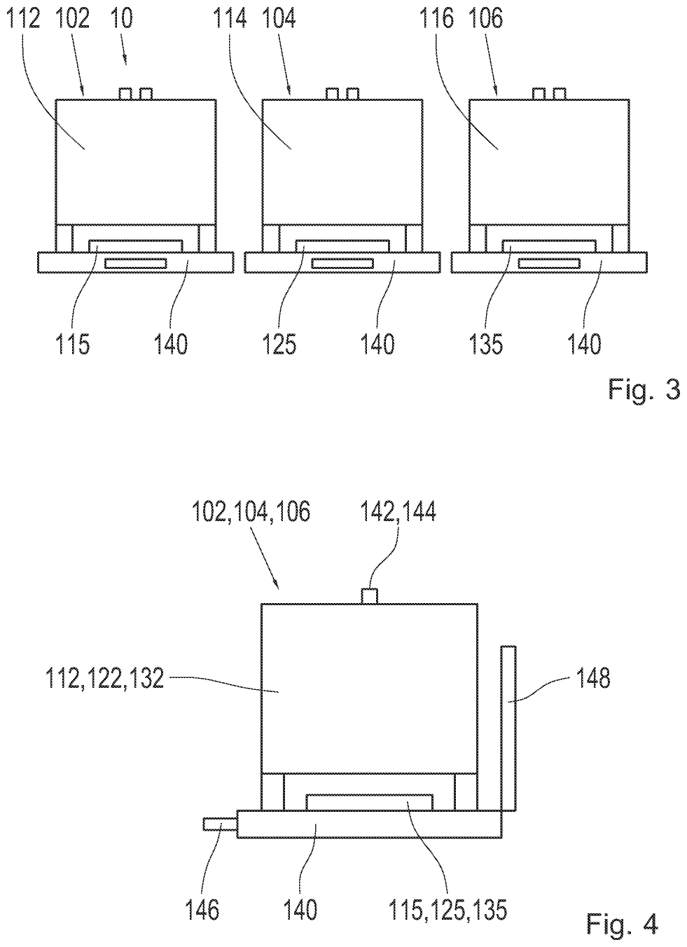

The power module 10 with the three sub-modules 102, 104, 106 is shown in an entirety of the power module 10 in FIG. 3. The sub-modules 102, 104, 106 are essentially identically formed and spaced apart from one another along a longitudinal direction. Preferably, the three substrates 140 are situated essentially in a plane.

FIG. 4 shows the particular sub-module 102, 104, 106 in a further side view. In addition to the components shown in FIG. 2, a control plate 148 is apparent here, which contains electronic components and electrical lines as well as signal lines (not shown), by which the gate electrodes of the corresponding half-bridge 115, 125, 135 can be actuated. Preferably, the control plate 148 extends perpendicularly to the substrate 140. The control plate 148 is arranged at one end of the substrate 140. The current output 146 is arranged at an end of the substrate 140 opposite the control plate 148 and protrudes beyond an end side of the substrate 140.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

### REFERENCE CHARACTERS

10 power module
102, 104, 106 sub-module
112, 122, 132 intermediate circuit capacitor
114, 124, 134 low-side switch
115, 125, 135 circuit-breaker group
116, 126, 136 high-side switch
118, 120 connecting element
140 substrate
142, 144 current input
146 current output
148 control plate

1-11. (canceled)

12. A power module (10) for operating an electric vehicle drive, comprising:
a plurality of circuit-breakers (114, 116, 124, 126, 134, 136) configured for generating an output current based on a supplied input current, the plurality of circuit- breakers (114, 116, 124, 126, 134, 136) having multiple groups (115, 125, 135), each of the groups (115, 125, 135) comprising two circuit-breakers (114, 116; 124, 126; 134, 136) connected in series; and
an intermediate circuit capacitor arrangement connected in parallel to the plurality of circuit-breakers (114, 116, 124, 126, 134, 136),
wherein the intermediate circuit capacitor arrangement comprises a plurality of intermediate circuit capacitors (112, 122, 132), each of the plurality of intermediate circuit capacitors (112, 122, 132) assigned to a respective one of the groups (115, 125, 135) of the circuit-breakers (114, 116, 124, 126, 134, 136) in order to form a sub- module (102, 104, 106) with the respective group (115, 125, 135).

13. The power module (10) of claim 12, wherein the multiple groups (115, 125, 135) of the circuit-breakers (114, 116, 124, 126, 134, 136) are connected in parallel, and each of the plurality of intermediate circuit capacitors (112, 122, 132) is connected in parallel to the respective group (115, 125, 135).

14. The power module (10) of claim 13, wherein, in at least one of the sub-modules (102, 104, 106), a respective one of the plurality of intermediate circuit capacitors (112, 122, 132) is arranged in a parallel connection directly next to the circuit-breakers (114, 116, 124, 126, 134, 136).

15. The power module (10) of claim 13, wherein, in each of the sub- modules (102, 104, 106), each group (115, 125, 135) of the circuit-breakers (114, 116, 124, 126, 134, 136) and the assigned intermediate circuit capacitor (112, 122, 132) are arranged at a respective one of a plurality of spatially separated substrates (140).

16. The power module (10) of claim 15, wherein the plurality of spatially separated substrates (140) are essentially situated coplanar.

17. The power module (10) of claim 15, wherein the plurality of spatially separated substrates (140) are essentially arranged successively along a longitudinal direction.

18. The power module (10) of claim 15, wherein each of the intermediate circuit capacitors (112, 122, 132) is situated on the respective one of a plurality of spatially separated substrates (140) such that each intermediate circuit capacitor (112, 122, 132) covers the respective group (115, 125, 135) of the circuit- breakers (114, 116, 124, 126, 134, 136).

19. The power module (10) of claim 15, wherein a control plate (148) is arranged at an end of each of the plurality of spatially separated substrates (140), wherein the control plate (148) comprises electronic components for actuating a gate electrode of the respective group (115, 125, 135) of the circuit-breakers (114, 116, 124, 126, 134, 136).

20. The power module (10) of claim 19, wherein the control plate (148) is aligned essentially perpendicular to the respective one of the plurality of spatially separated substrates (140).

21. The power module (10) of claim 19, wherein a current output contact (146) for outputting an output current based on an input current and generated by the circuit-breakers is arranged at an end of each of the plurality of spatially separated substrates (140) opposite the control plate (148).

22. The power module (10) of claim 12, wherein a current input contact (142, 144) for supplying an input current is arranged at the intermediate circuit capacitor (112, 122, 132) of at least one of the sub-modules (102, 104, 106).
